(19) United States
(12) Patent Application Publication
(10) Pub. No.: US 2007/0159795 A1
(43) Pub. Date: Jul. 12, 2007

(54) Linear power supply

(75) Inventor: Albert Cho, Taipei (TW)

Correspondence Address: BIRCH STEWART KOLASCH & BIRCH, PO BOX 747, FALLS CHURCH, VA, 22040-0747, US

(73) Assignee: Jui-Kai Tseng, Taipei (TW)

(21) Appl. No.: 11/330,227

(22) Filed: Jan. 12, 2006

(51) Int. Cl. H05K 7/20

(52) U.S. Cl. 361/695

(57) ABSTRACT

A linear power supply is used for supplying a voltage to an electronic device to drive the electronic device. The linear power supply includes a casing having a containing space disposed therein and at least one heat dissipating portion, and the containing space includes a circular coil and a circuit board electrically connected to the circular coil. With the foregoing measures, the linear power supply of the invention is lighter in weight, smaller in size, and better in heat dissipation than the prior art power supply that employs a silicon steel core.

### FIELD OF THE INVENTION

The present invention relates to a linear power supply, and more particularly to a linear power supply that adopts a circular coil and includes at least one heat dissipating portion.

### BACKGROUND OF THE INVENTION

Since a transformer can appropriately step up or down a voltage according to the turn ratio, the transformer is used extensively in different areas of electric appliances such as a battery charger, a lamp, or an electric appliance requiring a specific voltage. A general prior art transformer has an input end point disposed at an edge surface of its casing, and the input end point is usually in the form of a plug being inserted into a power socket for accessing public utility AC power, and an output end point connected to any edge surface other than that of the input end point of the casing, and the output end point is usually in the form of a terminal for transforming a voltage outputted to a negative load, so as to achieve the voltage transformation. The transformer comprises a plurality of rectangular bar shaped silicon steel plates and E-shape silicon steel plates stacked with each other, and a protruding coil is wound around the E-shape silicon steel plate, and the coils form a primary coil and a secondary coil, and the secondary coil is coupled to a high-voltage negative load.

R.O.C. Pat. Publication No. 00577625 entitled “Transformer structure” comprises: a primary coil stand and a secondary coil stand separately disposed on both sides of a H-shape groove stand of a transformer; a left grove and a right groove separately disposed on both sides of the H-shape groove stand, and the left groove is provided for containing the primary coil stand, and the right groove is provided for containing the secondary coil stand; a first hole disposed at the front end of the primary coil stand and a second hole disposed at the rear end of the primary coil stand and these holes are interconnected with each other; a first embedding groove disposed at an end of the front end of the first hole and a second embedding groove disposed at the rear end of the first hole; and an edge wall is maintained at the external side of the primary coil stand, and the edge wall is embedded with a terminal, and the front end of the secondary coil stand includes a hole and the edge of the secondary coil stand includes an embedding groove, and an edge wall is maintained at the external side of the secondary coil stand, and the edge wall includes an terminal. If the primary coil stand and the second coil stand are placed into the left groove and the right groove of the H-shape groove stand, a front containing space and a rear containing space are formed respectively. The front containing space is provided for installing a first iron core at the front side, and the rear containing space is provided for installing the second iron core at the rear side, such that the first iron core at the front side is connected to the second iron core at the rear side to define a complete closed magnetic circuit.

However, the foregoing prior art adopts the silicon steel iron core, and thus the volume of the prior art cannot be made smaller due to its internal structure, which goes against the trend emphasizing on light, thin, short, and compact design. Since the silicon steel core structure easily causes overheat, the user requirements cannot be complied. Therefore, a transformer adopting a circular coil is needed, and such transformer employing the circular coil has the following advantages over the prior art transformer employing the silicon steel core:

1. High Efficiency: It has excellent structural characteristics that can reduce 50% loss (compared with a transformer having an EI stacked plate iron core).

2. Power-Saving: The power consumption is reduced and the material consumption is lower, and thus greatly reducing the waste of global resources.

3. Light in Weight: The circular shape is perfect for the production design and structure, and thus can reduce the weight by 35%˜45%.

4. Small in Volume: Since the weight is reduced and the structure is simplified, therefore the space can be reduced by over 40% (compared with the traditional transformer having an EI stacked plate iron core).

5. Variable Sizes: The size can be designed flexibly to meet the requirements of the installation space of the product.

6. Easy Installation: The metal core is secured, and a resin is injected into the central hole for the fixing, and a fully sealed PC board results an easy installation.

7. Low Noise: It comes with no gaps or loosened parts, and thus the noise is only 10˜20% of the EI type transformer.

8. Low Magnetic Leakage: Since there is no gap or seam, therefore the magnetic leakage is only 20% of the EI type transformer.

### SUMMARY OF THE INVENTION

The primary objective of the present invention is to overcome the shortcomings of the prior art, avoid the existing deficiencies, and provide a feasible solution to solve the problems of poor heat dissipation and internal structure of the traditional power supply by means of a linear power supply that adopts a circular coil.

To achieve the foregoing objective, the linear power supply of the invention includes a casing having a containing space therein and at least one heat dissipating portion, and the containing space includes a circular coil and a circuit board electrically connected to the circular coil. With the foregoing measures, the linear power supply of the invention is lighter in weight, smaller in size, and better performance in heat dissipation than the prior art power supply that employs a silicon steel core.

### BRIEF DESCRIPTION OF THE DRAWINGS

FIG. 1 is a perspective view of a preferred embodiment of the present invention;

FIG. 2 is a schematic view of a structural layout according to a preferred embodiment of the present invention; and

FIG. 3 is a schematic view of a structural layout according to another preferred embodiment of the present invention.

### DETAILED DESCRIPTION OF THE PREFERRED EMBODIMENTS

The technical contents of the present invention will now be described in more detail hereinafter with reference to the accompanying drawings as follows:

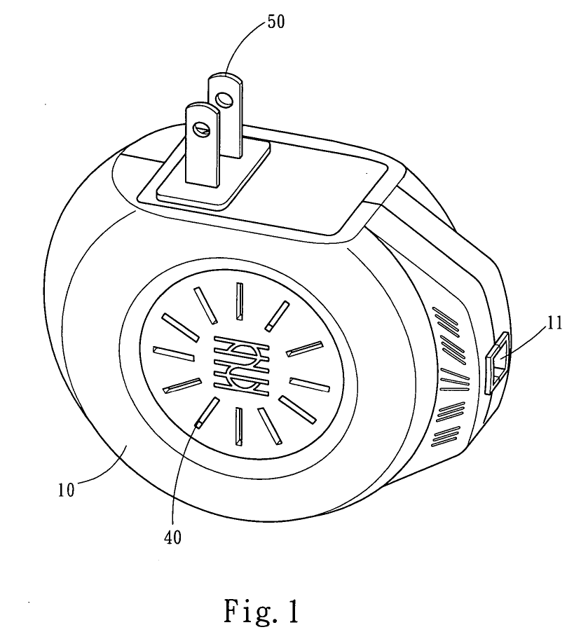

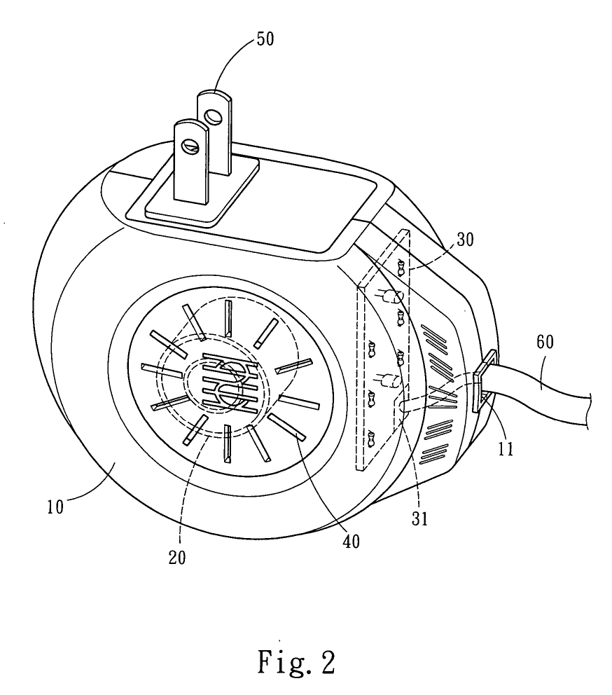

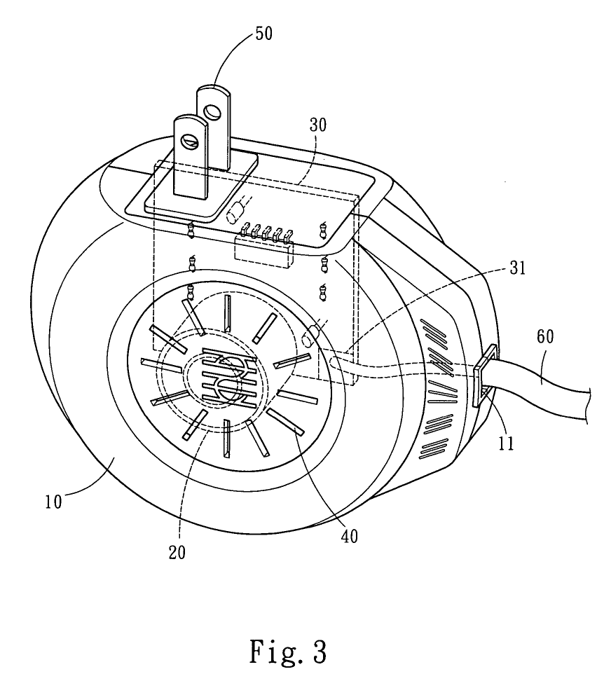

Referring to FIGS. 1 and 2 respectively for the perspective view and the schematic view of a structural layout according to the present invention, a linear power supply of the invention comprises a casing 10 having a containing space disposed therein, a circular coil 20 installed in the containing space, and a circuit board 30 installed in the containing space and electrically connected to the circular coil 20, and the circuit board 30 has the functions of rectifying a current, regulating a voltage, and controlling a circuit, and the casing 10 includes a plurality of heat dissipating portions 40 in a radiating shape and on the surface of both sides of the casing 10. The heat dissipating portions 40 disposed on the surface of both sides of the casing 10 are comprised of a plurality of through holes for maximizing the effect of dissipating heat and avoiding any overheat and damage to the power supply, and the casing 10 includes a plug 50 to be inserted into a power socket (not shown in the figure) for accessing the public utility AC power. The plug 50 is electrically connected to the circuit board 30, and the circuit board 30 has an output end 31 for outputting a voltage, and the casing 10 has a cable outlet 11 disposed at a position corresponding to the output end 31, and the output end 31 is electrically connected to a power cable 60. Through the cable outlet 11, the power cable 60 can be installed onto the casing 10. The present invention adopts the circular coil 20 to replace the traditional silicon steel core, and thus the overcall volume and weight of the linear power supply of the invention can be reduced, and the linear power supply of the invention is portable and does not occupy much space. Further the circular coil 20 is used, so that the exterior design of the casing 10 of the power supply is more flexible. Unlike the prior art power supply that adopts the silicon steel core, and the square and large design of the prior art power supply that employs the traditional silicon steel structure, the casing 10 according to a preferred embodiment of the invention has a circular arc appearance and is small in volume. Since the structure of the casing 10 of the invention allows a flexible arrangement of the circuit board 30, the installing position of the circuit board 30 can be adjusted as needed (see FIG. 3).

The linear power supply of the invention adopts the circular coil 20, so that the casing 10 can be made smaller, and the shape of the casing 10 is more flexible. The casing 10 could be in a circular arc shape, a cylindrical shape, or a polygonal shape to match with the radiating shape, rectangular bar shape, circular arc shape of the heat dissipating portion 40, and thus the linear power supply of the invention gives an artistic external look.

While the invention has been described by way of example and in terms of a preferred embodiment, it is to be understood that the invention is not limited thereto. To the contrary, it is intended to cover various modifications and similar arrangements and procedures, and the scope of the appended claims therefore should be accorded the broadest interpretation so as to encompass all such modifications and similar arrangements and procedures.

What is claimed is:

1. A linear power supply, used for supplying voltage to an electronic device, comprising:
a casing, having a containing space disposed therein;
a circular coil, installed in said containing space;
a circuit board, installed in said containing space and electrically coupled to said circular coil; and
at least one heat dissipating portion, disposed on said casing and corresponding to said circular coil.

2. The linear power supply of claim 1, wherein said casing includes a plug for accessing an external power supply, and said plug is electrically coupled to said circuit board.

3. The linear power supply of claim 1, wherein said circuit board includes an output end for outputting a voltage, and said casing includes a cable outlet disposed at a position corresponding to said output end.

4. The linear power supply of claim 1, wherein said casing is in a circular arc shape.

5. The linear power supply of claim 1, wherein said casing is in a cylindrical shape.

6. The linear power supply of claim 1, wherein said casing is in a polygonal shape.

7. The linear power supply of claim 1, wherein said heat dissipating portion includes at least one through hole disposed at the surface of said casing.

8. The linear power supply of claim 7, wherein said heat dissipating portion is in a radiating shape.

9. The linear power supply of claim 7, wherein said heat dissipating portion is in a rectangular bar shape.

10. The linear power supply of claim 7, wherein said heat dissipating portion is in a circular arc shape.
